(19) United States
(12) Patent Application Publication
(10) Pub. No.: US 2026/0011623 A1
(43) Pub. Date: Jan. 8, 2026

(54) LIQUID MEMS COOLING SYSTEM

(71) Applicant: Frore Systems Inc., San Jose, CA (US)

(72) Inventors: Suryaprakash Ganti, Los Altos, CA (US); Seshagiri Rao Madhavapeddy, La Jolla, CA (US); Ji Hoon Kim, Redwood City, CA (US); Ananth Saran Yalamarthy, San Jose, CA (US); Nai-Kuei Kuo, Los Gatos, CA (US)

(21) Appl. No.: 19/257,336

(22) Filed: Jul. 1, 2025

Related U.S. Application Data
(60) Provisional application No. 63/667,620, filed on Jul. 3, 2024.
(60) Provisional application No. 63/783,141, filed on Apr. 3, 2025.

(51) Int. Cl. H05K 7/20

(52) U.S. Cl. CPC H05K 7/20327

(57) ABSTRACT

A liquid cooling system is described. The liquid cooling system includes inlet(s), outlet(s), a manifold, and jet channels. The manifold is coupled to the inlet(s) and outlet(s). The jet channels are coupled to the manifold. The jet channels are microchannels. A portion of each of the jet channels is proximate to a heat-generating structure. The jet channels are configured such that a boundary layer in a liquid at a surface of a jet channel is not substantially developed within at least the portion of the jet channel proximate to the heat-generating structure. The jet channels are configured to receive fluid from the inlet(s) through the manifold and to provide the fluid through the manifold to the outlet(s). The jet channels and/or the manifold are configured to compensate for heating of the liquid in the cooling system.

### CROSS REFERENCE TO OTHER APPLICATIONS

This application claims priority to U.S. Provisional Patent Application No. 63/667,620 entitled LIQUID JET MEMS COOLING SYSTEM filed Jul. 3, 2024 and U.S. Provisional Patent Application No. 63/783,141 entitled LIQUID JET COOLING filed Apr. 3, 2025, both of which are incorporated herein by reference for all purposes.

### BACKGROUND OF THE INVENTION

As computing devices grow in speed and computing power, the heat generated by the computing devices also increases. Various mechanisms have been proposed to address the generation of heat. Active devices, such as fans, may be used to drive air through larger computing devices. Passive cooling devices, such as heat spreaders, may be used both in larger computing devices and in smaller, mobile computing devices, such as smartphones and tablet computers. However, such active and passive devices may be unable to adequately cool not only mobile devices and larger devices, but may also be inadequate for high power computing systems. For example, devices such as fans may be insufficient to cool systems containing graphics processing units (GPUs) and/or other server systems. Consequently, liquid cooling solutions for computing devices, particularly high-power dissipation computing devices, have been developed.

Conventional liquid cooling systems may provide improved heat management for high power dissipation computing devices, such as servers, GPUs, other accelerators, and/or other devices. Conventional liquid cooling systems utilize a pump to drive liquid (e.g., water) some distance to a cooling plate thermally coupled to the computing device and through the long microchannels of the cooling plate. A single microchannel of the cooling plate may extend across the cooling plate (e.g. along the entire length of a GPU). The liquid undergoes laminar flow through the microchannels and carries heat away with it. Liquid is driven from the cooling plate, optionally to a heat sink or chiller, and back to the pump. Although conventional liquid cooling systems may be an improvement over air cooling or passive cooling, further improvements are desired.

### BRIEF DESCRIPTION OF THE DRAWINGS

Various embodiments of the invention are disclosed in the following detailed description and the accompanying drawings.

FIGS. 1A-1C depict embodiments of liquid cooling systems.

FIGS. 2A-2H depict various views of an embodiment of a liquid cooling system.

FIGS. 3A-3C depict embodiments of liquid cooling systems having variations in the manifold.

FIGS. 4A-4D depicts embodiments of liquid cooling systems having variations in the jet channels.

FIGS. 5A-5E depicts embodiments of liquid cooling systems having variations in the jet channels.

FIG. 6 depicts graphs indicating the performance of embodiments of liquid cooling systems.

FIGS. 7A-7C depicts an embodiment of a liquid cooling system.

FIG. 8 is a flow-chart depicting an embodiment of a method for providing a liquid cooling system.

FIG. 9 is a flow-chart depicting an embodiment of a method for providing a liquid cooling system.

FIGS. 10-18B depict an embodiment of a liquid cooling system during fabrication.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

As semiconductor devices become increasingly powerful, the heat generated during operations also grows. Both passive components (e.g., heat spreaders, heat sinks, heat pipes, vapor chambers) and active components (e.g. fans and/or pumps that drive liquid) have been used in managing heat generated in computing devices. Liquid cooling may be desirable for cooling in high heat dissipation devices. However, there may be drawbacks. Conventional liquid cooling utilizes cooling plates to which liquid is driven, e.g., by a pump far from the cooling plate. The cooling plates are thermally coupled to a component, such as a GPU. Conventional microchannel cooling plates typically use long microchannels through which the fluid travels across the cold plate. The fluid carries heat away from the cold plate and, therefore, from the component. However, such liquid cooling systems typically have large pressure drops and may be inefficient. Even if cooling may be achieved for current devices, such systems may be unable to adequately function for future devices. Accordingly, an improvement in thermal management, particularly for high power devices, is desired.

A liquid cooling system is described. The liquid cooling system includes inlet(s), outlet(s), a manifold, and jet channels. The manifold is coupled to the inlet(s) and outlet(s). The jet channels are coupled to the manifold. The jet channels are microchannels. A portion of each of the jet channels is proximate to a heat-generating structure. The jet channels are configured such that a boundary layer in a liquid at a surface of a jet channel is not substantially developed within at least the portion of the jet channel proximate to the heat-generating structure. For example, the boundary layer may have apertures therein, may be thinned, and/or may not be present in the portion of the jet channel. The jet channels are configured to receive fluid from the inlet(s) through the manifold and to provide the fluid through the manifold to the outlet(s). The jet channels and/or the manifold are configured to compensate for heating of the liquid in the cooling system. The manifold and/or jet channels might include or consist of various materials, such a copper and/or semiconductor-thermal conductor. Some portions of the liquid cooling system (e.g., the manifold or portions thereof) may be formed of thermally insulating material(s). In some embodiments, active component(s), such as a pump or micro-pump, are present. The active component(s) are configured to drive a liquid flow through the manifold and the jet channels.

In some embodiments, the heat-generating structure includes at least one of a heat spreader, a vapor chamber, a semiconductor device, an integrated circuit, an optical device, a battery, a sensor, or a heat pipe. For example, the heat-generating structure may be one or more graphics processing units (GPUs) or a heat spreader thermally connected with the GPU. In some embodiments, the jet channel has a width of at least fifty micrometers and not more than five hundred micrometers and a length of at least fifty micrometers and not more than five hundred micrometers.

In some embodiments, the manifold includes an inlet manifold and an outlet manifold. The inlet manifold has an inlet plenum and manifold channels between the inlet plenum and the jet channels. The outlet manifold has an outlet plenum and outlet manifold channels. The jet channels are between the inlet plenum and the outlet plenum.

In some embodiments, the pitch, height, and/or width of the jet channels may be varied. For example, a first portion of the jet channels proximate to the inlet(s) may be less tall than a second portion of the jet channels distal from the inlet(s), at a different pitch (e.g. at a larger pitch) from than the second portion of the plurality of jet channels distal from the inlet(s), and/or narrower than the second portion of the jet channels distal from the inlet(s). A first portion of the inlet manifold proximate to the inlet may be narrower, have manifold channels at a larger pitch, and/or shorter than a second portion of the inlet manifold distal from the inlet.

In some embodiments, a first portion of the jet channels is coupled with the inlet(s) and a second portion of the jet channels is coupled with the outlet(s). The portion of the jet channels proximate to the heat-generating structure is between the first and second portions of the jet channels. The portion of the jet channels proximate to the heat-generating structure has a length not exceeding five hundred micrometers. In some embodiments, the jet channels have a first portion coupled to the manifold, a second portion at a first nonzero angle from the first portion, and a third portion coupled to the manifold and oriented at a second nonzero angle from the second portion. The third portion is coupled with the outlet(s).

In some embodiments, the manifold includes a central shaft coupled to the inlet and through which the liquid passes. The manifold may also include an outer manifold. In such embodiments, the jet channels are configured to carry the liquid from the central shaft to an outer manifold or from the outer manifold to the central shaft. The jet channels may be oriented radially from the central shaft to the outer manifold. In some such embodiments, the liquid cooling system has a hexagonal footprint. The cooling system may be one of a number of cooling systems having the hexagonal footprint and configured with sides that are adjacent. The width and/or height of the central shaft may be varied between individual cooling systems. The variation in height may be used to compensate for heating of the liquid as the liquid travels through the cooling system or based on hot spots in the heat-generating structure.

A liquid cooling system including inlet(s), outlet(s), a manifold, and jet channels coupled with the manifold is described. The manifold includes an inlet manifold and an outlet manifold. The inlet manifold is coupled to the inlet(s). The outlet manifold is coupled to the outlet(s). The jet channels are coupled with the manifold. Each of the jet channels is a microchannel. A portion of each of the jet channels is proximate to a heat-generating structure. The jet channels are configured to receive a liquid from the inlet manifold and to provide the liquid to the outlet manifold. The portion of each jet channel proximate to the heat-generating structure has a length not exceeding five hundred micrometers. At least one of the jet channels or the manifold is configured to compensate for heating of the liquid in the cooling system.

A method for providing a liquid cooling system is described. The method includes providing a manifold configured to be coupled to at least one inlet and at least one outlet. The method also includes providing jet channels. The plurality of jet channels are microchannels. A portion of each of the jet channels is proximate to a heat-generating structure. The jet channels are configured such that a boundary layer in a liquid at a surface of a jet channel is not substantially developed within at least the portion of the jet channel proximate to the heat-generating structure. At least one of the jet channels or the manifold is configured to compensate for heating of the liquid in the cooling system.

In some embodiments, providing the jet channels further includes providing a jet channel subassembly. Providing a jet channel subassembly may include providing a base layer and providing jet channel layers. Each of the jet channel layers has apertures corresponding to the plurality of jet channels. Providing the jet channel subassembly may also include diffusion bonding the jet channel layers together with the base layer.

In some embodiments, the manifold includes manifold channels configured to be fluidically coupled with the jet channels. Providing the manifold may further include providing manifold layers including manifold apertures corresponding to the manifold channels and diffusion bonding the plurality of manifold layers together. In some embodiments, fabrication of the liquid cooling system also includes diffusion bonding the manifold with the jet channel subassembly. A cover plate is affixed to the manifold. The cover plate includes at least one of inlet(s) or outlet(s). Affixing the cover plate to the manifold may include performing a brazing process.

Using an embodiment of the liquid cooling system described herein (which includes liquid jet channels), a significant improvement may be achieved. The cooling system including the liquid jet channels may provide superior cooling at lower flow rates. Further, hot spots may be mitigated. Consequently, performance of the heat-generating device coupled to the liquid cooling system may be enhanced.

The cooling systems and methods are described in the context of various features. The features of cooling systems and method(s) described herein may be combined in various ways not explicitly depicted. For example, the pitch and width of both the inlet manifold channels and the jet channels might be varied, multiple inlets and/or outlets may be used, and/or the cooling systems may extended to cover a larger (or smaller) region.

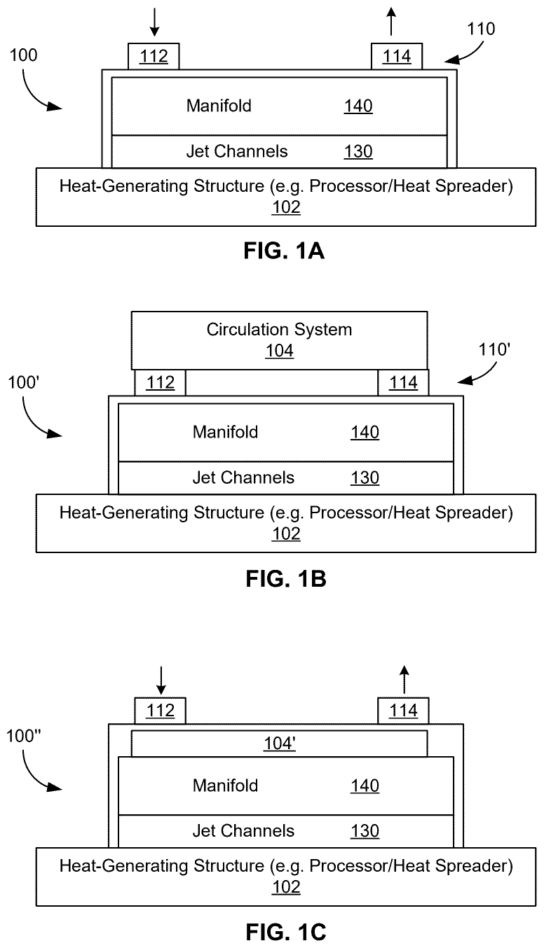

FIGS. 1A, 1B, and 1C depict embodiments of liquid cooling systems 100, 100′, and 100″. For clarity, only portions of cooling systems 100, 100′, and 100″ are shown. Also depicted in FIGS. 1A-1C is heat-generating structure 102. Heat-generating structure 102 may include semiconductor component(s) including individual integrated circuit components such as processors, other integrated circuit(s) and/or chip package(s); sensor(s); optical device(s); one or more batteries; other component(s) of an electronic device such as a computing device; heat spreaders; heat pipes; other electronic component(s) and/or other device(s) desired to be cooled. The heat-generating structure 102 may be a high-power dissipation component, such as a GPU. Consequently, heat-generating structure 102 may be referred to herein as a GPU.

Referring to FIG. 1A, liquid cooling system 100 includes liquid exchange region 110. Liquid exchange region 110 includes inlet 112 and outlet 114. In some embodiments, liquid flows into cooling system 100 through inlet 112 and out via outlet 114. In some embodiments, liquid may flow out through inlets 112 and in through outlet 112. Thus, the direction of liquid flow may be reversible in some embodiments. Although one inlet 112 and one outlet 114 are shown, another number may be present. For example, liquid cooling system 100 may have two inlets 112 and one outlet 114, two outlets 114 and one inlet 112, or another number of inlets 112 and/or outlets 114.

Cooling system 100 also includes jet channels 130 and manifold 140. Manifold 140 is coupled with inlets 112, outlets 114, and jet channels 130. Jet channels 130 are microchannels. For example, jet channels 130 may have a width of at least twenty micrometers and not more than five hundred micrometers. In some embodiments, jet channels 130 may have a width of at least fifty micrometers. In some embodiments, jet channels 130 have a width of not more than two hundred micrometers. In some embodiments, jet channels 130 have a width of not more than one hundred micrometers. Liquid flows into cooling system 10 via inlet 112, through manifold 140 to jet channels 130, through jet channels 130, back through manifold 140, and exits via outlet 112.

A portion of each of jet channels 130 is proximate to heat-generating structure 102. For example, jet channels 130 may be coupled to heat-generating structure 102 via thermal conduction. Jet channels 130 are configured such that a boundary layer in a liquid at a surface of a jet channel is not substantially developed within at least the portion of the jet channel proximate to heat-generating structure 102. For example, the boundary layer may have apertures therein, be thinned, and/or not be present in the portion of the jet channel proximate to heat-generating structure 102. The reduced or missing boundary layer may correspond to a length of jet channels 130. In some embodiments, the portion of jet channels 130 proximate to heat-generating structure 102 has a length of not more than five hundred micrometers. In some embodiments, this portion of jet channels 130 is not more than two hundred micrometers long. In some embodiments, this potion of each jet channel 130 is at least fifty micrometers or at least one hundred micrometers in length.

Jet channels 130 and/or manifold 140 might include or consist of various materials to manage heat transfer. In some embodiments, jet channels 130 and/or manifold 140 may be or include thermally conductive materials, such copper and/or semiconductor-thermal conductor(s). Jet channels 130 may be thermally conductive in order to provide good thermal contact to heat-generating structure 102. In some embodiments, some or all manifold 140 is thermally insulating. Similarly, a portion of jet channel 130 distal from heat-generating structure 102 may be thermally insulating.

Jet channels 130 and/or manifold 140 are configured to compensate for heating of the liquid in the cooling system 100. As liquid travels through cooling system 100, heat is transferred to the liquid. As a result, the liquid may have a higher temperature closer to outlet 112 than at inlet. Without compensation, this may adversely affect the ability of cooling system 100 to cool regions of heat-generating structure 102 proximate to outlet 114. In addition, it may be desirable to avoid hot spots (regions of locally higher temperature) in heat-generating structure 102. This may be challenging if the increase in temperature of the liquid passing through cooling system 100 is not accounted for. Thus, the geometry and/or materials used for jet channels 130 and/or manifold 140 compensates for (e.g. mitigates) heating of the liquid. For example, manifold 140 may be formed of an insulator. In such embodiments, heat carried by the liquid less likely to be transferred to the (thermally insulating) manifold 140. The geometry of manifold 140 and/or get channels 130 may be configured to compensate for heating of the fluid. For example, jet channels 130 may be more sparsely distributed proximate to inlets 112. Other techniques are possible.

Liquid cooling system 100 may have improved performance. Because the boundary layer in jet channels 130 is reduced or eliminated, heat transfer between the sidewalls of jet channels 130 and the liquid is improved. Thus, cooling system 100 is better able to transfer heat from heat-generating structure 102 to the liquid. Cooling system 100 may provide improved cooling at lower flow rates of the liquid. As a result, cooling system 100 may improve thermal management for heat-generating structure 102. Performance of heat-generating structure 102 may be improved. Further, manifold 140, jet channels 130, or both manifold 140 and jet channels 130 are configured to compensate for heating of the liquid as the liquid traverses cooling system 100. Thus, the temperature of cooling system 100 and heat-generating structure 102 may be more uniform. Hot spots for heat-generating structure 102 may be reduced. Thus, performance of heat-generating structure may again be improved.

Referring to FIG. 1B, cooling system 100′ is analogous to cooling system 100. Cooling system 100′ thus includes jet channels 130, manifold 140, inlet 112, and outlet 114 that are analogous to those described in the context of cooling system 100. Also explicitly shown is liquid circulation system 104. Liquid circulation system 104 may include a pump or other component that drives the flow of liquid into inlet 110, through manifold 140 to jet channels 130, through jet channels 130, back through manifold 140 and out of outlet 112. A pump used in connection with circulation system 104 may be proximate to or relatively far from liquid cooling system 100. Liquid circulation system 104 may also include a heat sink, chiller, or other component used to cool the hot liquid from cooling system 100′.

Cooling system 100′ operates in an analogous manner to cooling system 100 and may share the benefits of cooling system 100. Thus, cooling system 100′ may provide improved cooling and thermal management for heat-generating structure 102.

Referring to FIG. 1C, cooling system 100″ is analogous to cooling systems 100 and 100′. Cooling system 100″ thus includes jet channels 130, manifold 140, inlet 112, and outlet 114 that are analogous to those described in the context of cooling system 100. Inlets 112 and outlets 114 may be used to receive liquid at and remove liquid from cooling system 100. In cooling system 100′, liquid circulation system 104′ is incorporated into cooling system 100″. For example, liquid circulation system 104′ may include active component(s) such as a pump or micro-pump. The active component(s) are configured to drive a liquid flow through manifold 140 and jet channels 130. Liquid circulation system 104 may also include a heat sink, chiller, or other component used to cool the hot liquid from cooling system 100′. In some embodiments, such heat sinks are spaced apart from cooling system 100″ (e.g., accessible via inlet 112 and outlet 114).

Cooling system 100″ operates in an analogous manner to cooling systems 100 and 100′. Thus, cooling system 100″ may share the benefits of cooling system 100. Thus, cooling system 100′ may provide improved cooling and thermal management for heat-generating structure 102.

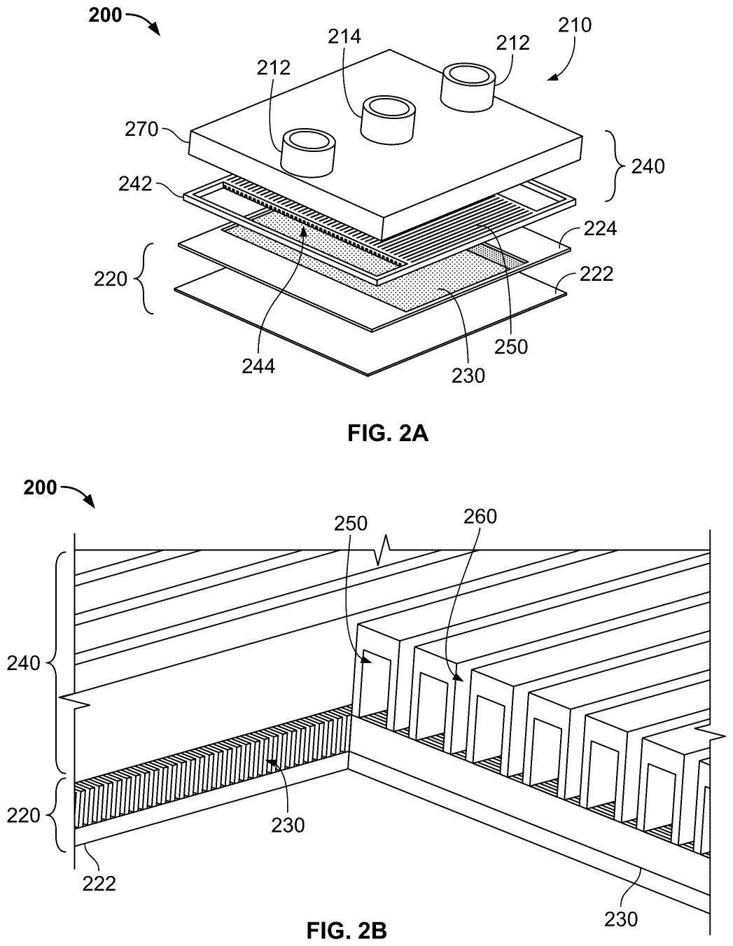

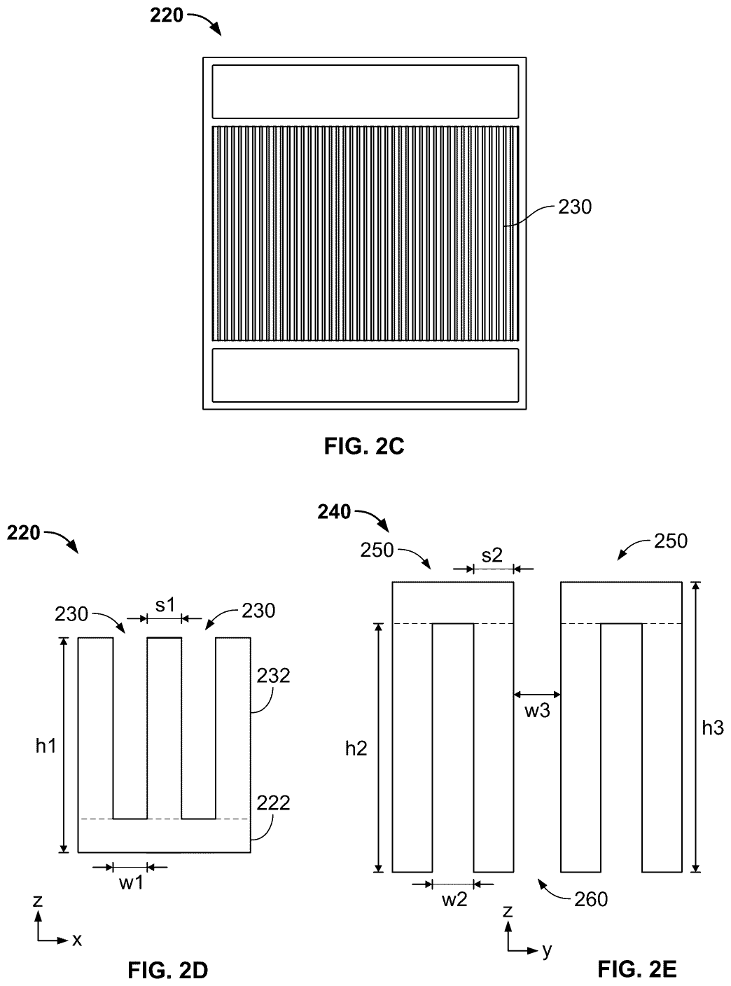

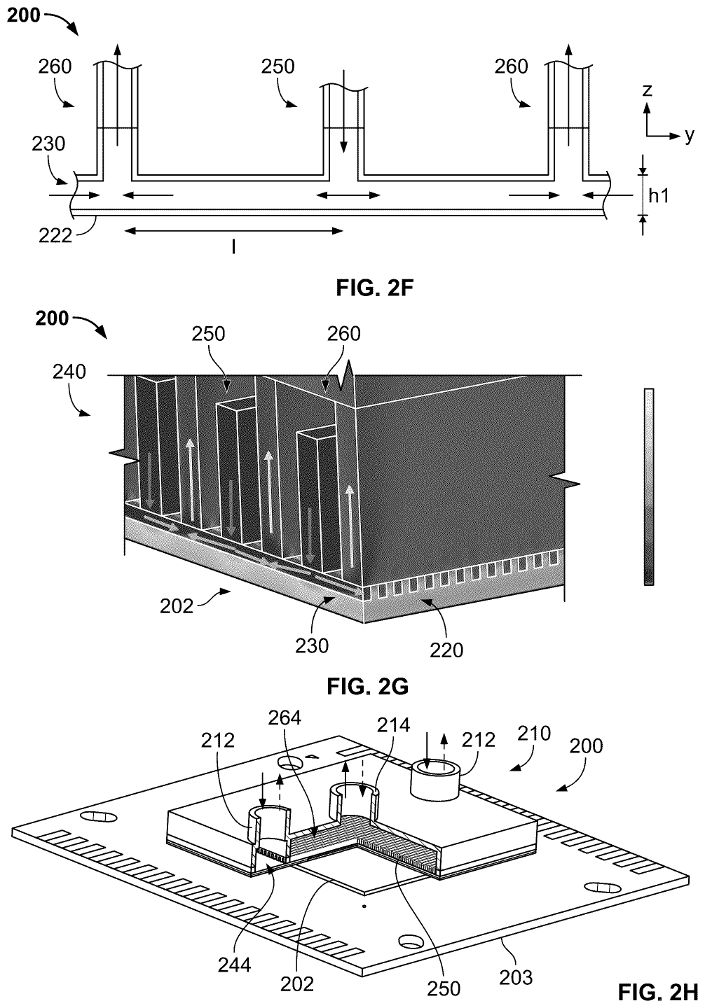

FIGS. 2A-2H depict various views of an embodiment of liquid cooling system 200. FIGS. 2A-2H may not be to scale. FIG. 2A depicts an exploded view of cooling system 200. FIG. 2B depicts a close-up view of a portion of cooling system 200. FIG. 2C depicts a plan view of jet channel subassembly 220. FIG. 2D depicts a cross-sectional view of a portion of jet channel subassembly 220. FIG. 2E depicts a cross-sectional view of a portion of manifold 240. FIG. 2F depicts a cross-sectional view of a portion of jet channel subassembly 220 and manifold 240. FIG. 2G depicts the flow and temperature of liquid flow in cooling system 200. In other words, the flow of liquid as opposed to the walls of cooling system 200 are shown. The structure may be inferred from the location of the liquid. FIG. 2H depicts cooling system 200 as used with an integrated circuit (i.e. a heat-generating structure) 202 on a circuit board. For clarity, only portions of cooling system 200 are shown.

Also depicted in FIGS. 2A-2H is heat-generating structure 202. Heat-generating structure 202 (depicted in FIG. 2H) may include semiconductor component(s) including individual integrated circuit components such as processors, other integrated circuit(s) and/or chip package(s); sensor(s); optical device(s); one or more batteries; other component(s) of an electronic device such as a computing device; heat spreaders; heat pipes; other electronic component(s) and/or other device(s) desired to be cooled. The heat-generating structure 102 may be a high-power dissipation component, such as a GPU. Consequently, heat-generating structure 102 may be referred to herein as a GPU.

Cooling system 200 includes jet channel subassembly 220 including base plate 222 and jet channel plate(s) 224 having jet channels 230, manifold 240, inlets 212, outlet 214, and cover plate 270. Cooling system 200 is analogous to cooling system 100. For example, jet channels 230, manifold 240, inlets 212, and outlet 214 are analogous to jet channels 130, manifold 140, inlets 112, and outlet 114, respectively. Thus, the structure and function of jet channels 230, manifold 240, inlets 212, and outlet 214 are analogous to those of jet channels 130, manifold 140, inlets 112, and outlet 114, respectively.

Jet channel subassembly 220 includes a base plate 222 and additional plate 224 having jet channels 230 therein. Base plate 222 may be thermally coupled with heat-generating structure 202. For example, base plate 222 coupled liquid cooling system 200 to heat-generating structure via thermal conduction. Thus, base plate 222 may include or be formed of high thermal conductivity material(s), such as copper.

Manifold 240 includes inlet manifold 242 and an outlet manifold including outlet manifold channels 260. Inlet manifold 242 includes inlet manifold channels 250. As can be seen in FIGS. 2B and 2G, inlet manifold channels 250 and outlet manifold channels 260 are oriented at a nonzero angle from jet channel 230. In the embodiment shown, inlet manifold channels 250 and outlet manifold channels 260 are substantially perpendicular to (e.g., oriented 85 degrees −95 degrees from) jet channels 230. Other angles are possible. Inlet manifold channels 250 and outlet manifold channels 260 are configured to be fluidically coupled with jet channels 230. Thus, fluid flows between inlet manifold channels 250 and outlet manifold channels 260 via jet channels 230. Cover plate may be used to form inlet plenum 244 and outlet plenum 264 for manifold 240.

Jet channels 230 are microfluidic channels. For example, as indicated in FIG. 2D, jet channels 230 may have a width w1, a spacing (or jet channel wall width) s1, and a height h1. In some embodiments, the width of jet channels is at least fifty micrometers and not more than five hundred micrometers (or not more than two hundred micrometers, or not more than one hundred micrometers). For example, the width w1 may be nominally sixty through seventy micrometers. The spacing s1, or wall width, of jet channels 230 may be at least fifty nanometers and not more than two hundred nanometers. The height h1 of jet channels 230 may be at least fifty nanometers and not more than five hundred nanometers. In some embodiments, the height may be at least seventy-five nanometers and not more than four hundred nanometers. Although jet channels 230 are indicated as having the same height and a constant pitch, the height, width, pitch, and/or length may vary. As indicated in FIG. 2F, the length of jet channels 230 proximate to heat-generating structure 202 (and base plate 222) is 1. The length is configured such that a boundary layer in a liquid at a surface of jet channel 230 is not substantially developed within at least the portion of the jet channel proximate to heat-generating structure 202. For example, the boundary layer may have apertures therein, may be thinned (i.e. thinner than a boundary layer for a jet channel of the same width and height but which is longer-e.g., 1 mm or more), and/or may not be present in the portion of jet channel 230 proximate to heat-generating structure 202. In cooling system 200, the boundary layer is not substantially developed along length l.

Inlet manifold channels 250 and outlet manifold channels 260 may be larger than jet channels 230. For example, FIG. 2E depicts manifold 240. Inlet manifold channels 250 have a height h2, a width w2, and a wall width (or spacing from outlet manifold channel 260) s2. Outlet manifold channels 260 have a width w3 and a height h3. The inlet manifold height h2 may be at least five hundred micrometers and not more than four millimeters. The inlet manifold width w2 may be at least fifty micrometers and not more than five hundred micrometers. The inlet manifold wall width s2 may be at least one hundred micrometers and not more than one thousand micrometers. The outlet manifold height h3 may be at least seven hundred and fifty micrometers and not more than five millimeters. The outlet manifold width w3 may be at least fifty micrometers and not more than five hundred micrometers. For example, in some embodiments, h3 may be 900-1100 micrometers, w3 may be in the range of 90-210 micrometers (and may taper), s2 may be 190-410 micrometers (and may taper), h2 may be 700-800 micrometers, and w2 may be may be 90-210 micrometers (and may taper). In some embodiments, boundary layers may develop within inlet manifold channels 250 and/or outlet manifold channels 260. For example, during flow downward (along h2) or upward (along h3) a boundary layer may develop. However, heat transfer from heat-generating device 202 to the liquid may not principally occur in manifold 240. Thus, the presence of the boundary layer may not adversely affect performance of cooling system 200. In some embodiments, inlet plenum 244 and/or outlet plenum 264 may have heights of nominally at least three millimeters and not more than eight millimeters. Different dimensions for jet channels 230, inlet manifold channels 250, outlet manifold channels 260, inlet plenum 244, and/or outlet plenum 264 may be possible in some embodiments.

In operation, liquid flows to liquid cooling system 200 via inlets 212 and into inlet plenum 244. Inlet manifold channels 250 distribute the liquid to jet channels 230. Flow may be viewed as substantially downward through inlet manifold channels 250 to jet channels 230. This is indicated in FIGS. 2F and 2G. Thus, manifold 240 distributes the flow of liquid from inlet plenum 244 into a dense layer of jet channels 230. The liquid flows through jet channels 230 proximate to base plate 222 and, therefore, heat-generating device 202. The liquid flows through jet channels 230 may be viewed as substantially horizontal. As it flows through jet channels 230, the liquid absorbs heat from heat-generating structure 202. Because jet channels 230 are formed of a high thermal conductivity material, such as copper, the heat may transfer to the liquid from base plate 222 and sidewalls of jet channels. Because jet channels 230 are configured such that a boundary layer does not develop or is thinned/has apertures therein, the transfer of heat to the liquid is more efficient. The heated liquid flows through outlet manifold channels 260 to outlet plenum 264. The flow of liquid through outlet manifold channels 260 may be viewed as being substantially upwards. The heated liquid may exit cooling system 200 via outlet 214. The flow of liquid within cooling system 200 may be driven by gravity (traveling vertically in manifold 240 and through jet channels 230) only. Thus, cooling system 200 itself may be passive. In some embodiments, liquid may be driven within liquid cooling system 200 by active element(s) (e.g., see a micropump). In some embodiments, liquid may be driven through the cooling system 200 by gravity and active element(s). Liquid may be brought to inlet 212 and taken from outlet 214 based on gravity only or by a pump or other active device (not shown in FIGS. 2A-2H).

Although described in the context of inlets 212 and outlet 214, in some embodiments, the liquid may flow in the opposite direction. Thus, liquid may flow to outlet 214 (near the central region of cooling system 400), through outlet plenum 264, down through outlet manifold channels 260 to jet channels 130, to inlet manifold channels 250, to plenum 244 and out via inlets 212. Thus, the direction of flow may be reversible. This is indicated in FIG. 2H by the unlabeled arrows. Solid arrows indicate one direction of flow, while dashed arrows indicate the reverse direction of flow. Thus, in some embodiments, liquid flow from inlets 212 to outlet 214 or from outlets 214 to inlet 214. In either case, jet channels 230 are configured such that a boundary layer substantially does not develop within the portion of the jet channels 230 proximate to heat-generating structure 202 (e.g. adjacent to the surfaces of the bottom plate 222 or sidewalls of the jet channel). Because of the lack of (or thinned/discontinuous) boundary layer in jet channels 230, heat transfer between the walls and/or floor of jet channels 230 (and thus heat-generating structure 202) and the liquid is increased. Cooling efficiency may be greatly enhanced.

Heated liquid exits liquid cooling system 200 travels through outlet plenum 264/outlet 214 or via inlet 212. To do so, the heated liquid may travel a relatively large distance. For example, heat-generating structure 202 may be a GPU. Such a device may have a footprint on the order of thirty millimeters by fifty millimeters. Without more, the flow of heated liquid in cooling system 200 might adversely affect performance. Moreover, there may be a significant pressure drop through cooling system 200 that affects flow. Consequently, jet channels 230 and/or manifold 240 are configured to compensate for the heating of the liquid. In some embodiments, jet channels 230 and/or manifold 240 may compensate for pressure and/or flow drops. As used herein, compensate may include partially or fully compensating for the heating and/or pressure changes. For example, in some embodiments, manifold 240 may be formed of a thermally insulating material. In such embodiments, heat from jet channels 230 may not heat the walls of manifold 240. In some embodiments, the pitch, height, and/or width of jet channels 230, input manifold channels 250 and/or output manifold channels 260 may be engineered to account for the heating of liquid and/or pressure drop. Thus, performance of cooling system 200 may be improved.

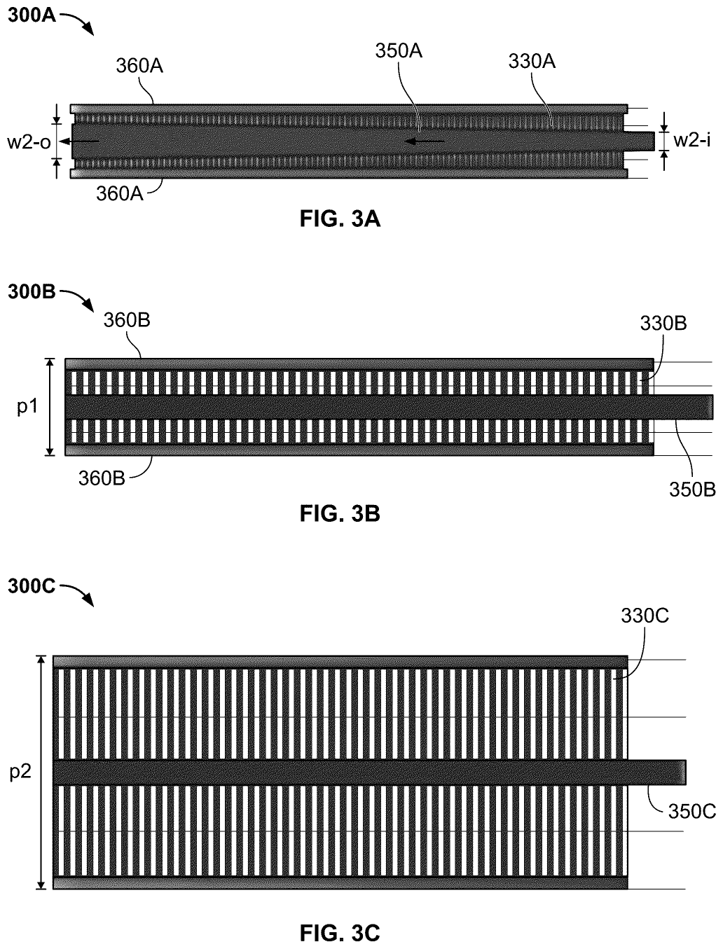

FIGS. 3A-3C depict embodiments of portions of liquid cooling systems 300A, 300B, and 300C, respectively, having variations in the manifold. FIGS. 3A-3C may not be to scale and all portions of liquid cooling systems 300A, 300B, and 300C are not shown. FIGS. 3A-3C depict the fluid domain. Thus, the liquid flowing through, as opposed to the structure of cooling systems 300A, 300B, and 300C are shown. The structure may be inferred from the location of the liquid.

Referring to FIG. 3A, cooling system 300A includes a manifold having input manifold channel 350A (of which only one is shown) and output manifold channels 360A that are analogous to input manifold channels 250 and output manifold channels 260. Jet channels 330A are analogous to jet channels 230. The flow of liquid through input manifold channel 350A is indicated by unlabeled arrows. The width of input manifold channel 350A tapers from a smaller width w2-i at the inlet to w2-o closer to the outlet. Although input manifold channel 350A is shown as tapering linearly, the taper may be made in another manner. For example, the width of input manifold channel may be stepped and/or in accordance with a higher order curve.

Because input manifold channel 350A is tapered, the flow of cool liquid provided by input manifold channel 350 increases proximate to the output. Thus, fluid flow may be increased closer to the output. This may mitigate the increase in temperature due to heating of the liquid in cooling system 300. Temperature uniformity may be improved and hot spots reduced. Thus, performance of cooling system 300 may be enhanced.

Referring to FIGS. 3B-3C, cooling systems 300B and 300C include a manifold having input manifold channels 350B and 350C (of which only one is shown) and output manifold channels 360B and 360C that are analogous to input manifold channels 250 and output manifold channels 260. Jet channels 330B and 330C are analogous to jet channels 230. The pitch of input manifold channels 350B is smaller than that of input manifold channels 350C (i.e., p1<p2). As a result, liquid flows more quickly through cooling system 300B than through cooling system 300C. The pitches of cooling systems 300B and 300C may be used at different portions of a cooling system to mitigate hot spots and/or account for heating of the liquid used. For example, the pitch p2 of cooling system 300C may be used proximate to the inlet of the cooling system (e.g. item 212 or 214 in FIGS. 2A-2H) while the pitch of cooling system 300B may be used proximate to the outlet (e.g. item 214 or 212 in FIGS. 2A-2H). In some embodiments, a portion of the heat-generating structure may be cooled by cooling system 300B, while another (lower power) portion of the heat-generating structure may be cooled by cooling system 300C. Thus, the cooling system may be tailored to compensate for heating of fluid and/or variations in heat generated by the device to be cooled. Consequently, performance may be improved.

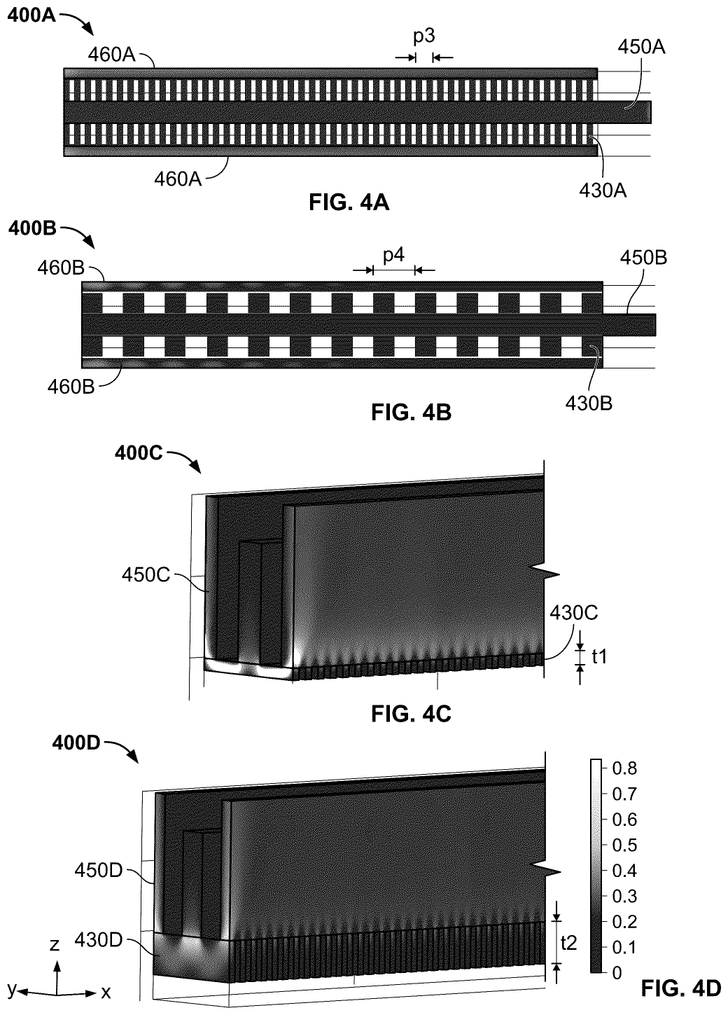

FIGS. 4A-4D depicts embodiments of liquid cooling systems 400A, 400B, 400C, and 400D having variations in the jet channels. FIGS. 4A-4D may not be to scale and all portions of liquid cooling systems 400A, 400B, 400C, and 400D are not shown. FIGS. 4A-4D depict the fluid domain. Thus, the liquid flowing through, as opposed to the structure of cooling systems 400A, 400B, 400C, and 400D are shown. The structure may be inferred from the location of the liquid.

Referring to FIGS. 4A and 4B, plan views of cooling systems 400A and 400B are shown. Cooling systems 400A and 400B include a manifold having input manifold channel 450A and 450B (of which only one is shown) and output manifold channels 460A and 460B that are analogous to input manifold channels 250 and output manifold channels 260. Jet channels 430A and 430B are analogous to jet channels 230. A comparison of jet channels 430A and 430B indicates that not only are jet channels 230B wider, but the pitch is greater. As a result, liquid flows at a different rate through cooling system 400B than through cooling system 400A. The pitches of cooling systems 400A and 400B may be used at different portions of a cooling system to mitigate hot spots and/or account for heating of the liquid used. Thus, the cooling system may be tailored to compensate for heating of fluid and/or variations in heat generated by the device to be cooled. Consequently, performance may be improved.

Referring to FIGS. 4C and 4D, perspective views of cooling systems 400C and 400D are shown. Cooling systems 400C and 400D include a manifold having input manifold channel 450C and 450C (of which only one is shown) and output manifold channels 460A and 460B that are analogous to input manifold channels 250 and output manifold channels 260. Jet channels 430C and 430D are analogous to jet channels 230. A comparison of jet channels 430C and 430D indicates that jet channels 230D are taller than jet channels 430C. As a result, liquid flows at a different rate through cooling system 400B than through cooling system 400A. The pitches of cooling systems 400A and 400B may be used at different portions of a cooling system to mitigate hot spots and/or account for heating of the liquid used. For example, jet channels 430C may be used proximate to the inlet (e.g. 212 or 214, depending on the direction of liquid flow), while jet channels 430D might be used closer to the outlet. Thus, the cooling system may be tailored to compensate for heating of fluid and/or variations in heat generated by the device to be cooled. Consequently, performance may be improved.

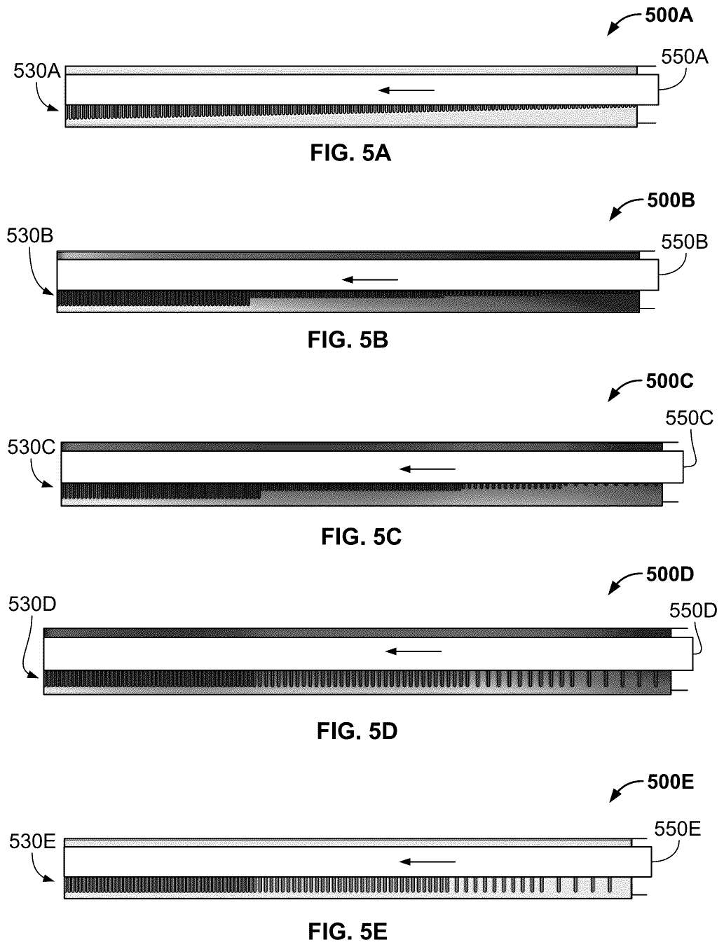

FIGS. 5A-5E depicts cross-sectional views of embodiments of liquid cooling systems 500A, 500B, 500C, 500D and 500E having variations in the jet channels. FIGS. 5A-5E may not be to scale and all portions of liquid cooling systems 500A, 500B, 500C, 500D, and 500E are not shown. Different variations in jet channel height and pitch are shown. Other variations are possible.

Cooling systems 500A, 500B, 500C, 500D, and 500E include a manifold having input manifold channel 550A, 550B, 550C, 500D, and 550E (of which only one is shown) that are analogous to input manifold channels 250. Jet channels 530A, 530B, 530C, 530D, and 530E are analogous to jet channels 230. Jet channels 530A vary in height, tapering smoothly from shorter to taller jet channels. Jet channels 530B also vary in height. However, the taper from lower to greater height is accomplished in steps. Jet channels 530C vary in both pitch and height. Thus, the pitch and height both increase. Jet channels 530D vary in pitch from lower to higher pitch. Jet channels 530E vary in pitch from lower to higher pitch, but in a different manner than for jet channels 530D. The direction of fluid flow is shown by unlabeled arrows in inlet manifold channels 550A, 550B, 550C, 550D, and 550E. Because of the variations in pitch and/or height, liquid may have a higher flow further from the inlet. This higher flow through jet channels 530A, 530B, 530C, 530D, and 530E may compensate for heating of fluid within cooling systems 500A, 500B, 500C, 500D, and 500E. Consequently, performance may improve.

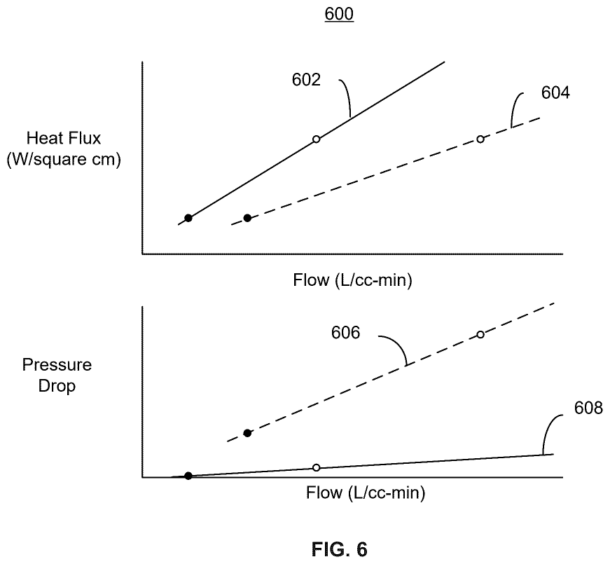

FIG. 6 depicts graphs 600 indicating the performance of embodiments of liquid cooling systems described herein. In particular, the heat flux dissipated and pressure drop for cooling systems described herein are compared with conventional liquid cooling systems. The dark circles represent current devices and the open circles represent future devices desired to be cooled. Curves 602 and 608 correspond to the devices described herein, while dashed curves 604 and 606 represent conventional devices. As indicated by a comparison of curves 602 and 608 with curves 604 and 606, cooling systems described herein may provide superior cooling at a lower pressure drop. Thus, cooling systems described herein may provide superior cooling at lower flows and lower pressure drops. Performance of the device being cooled may, therefore, be improved.

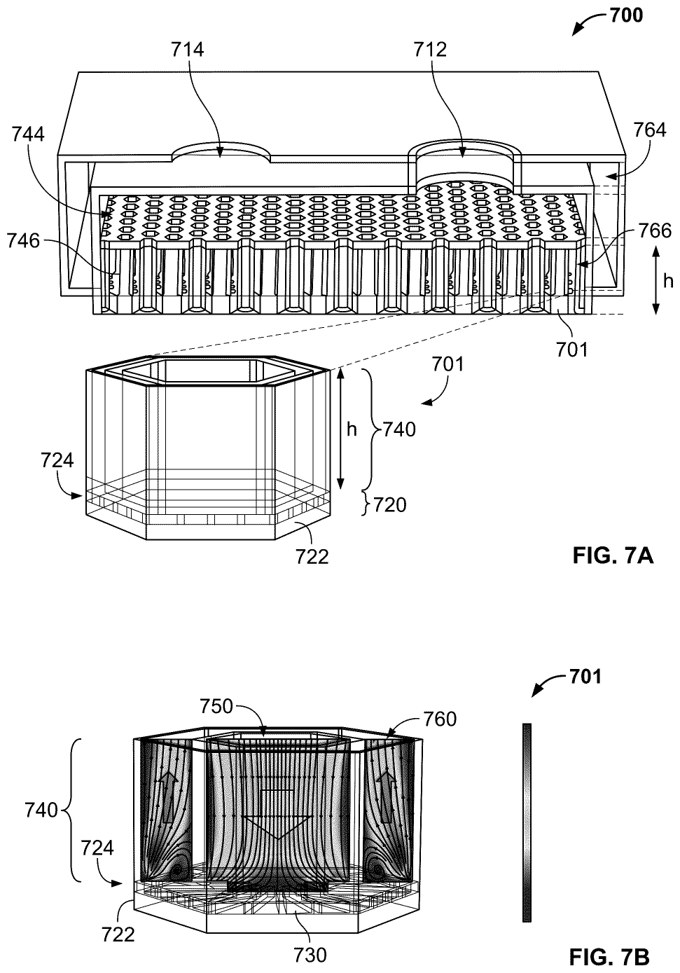

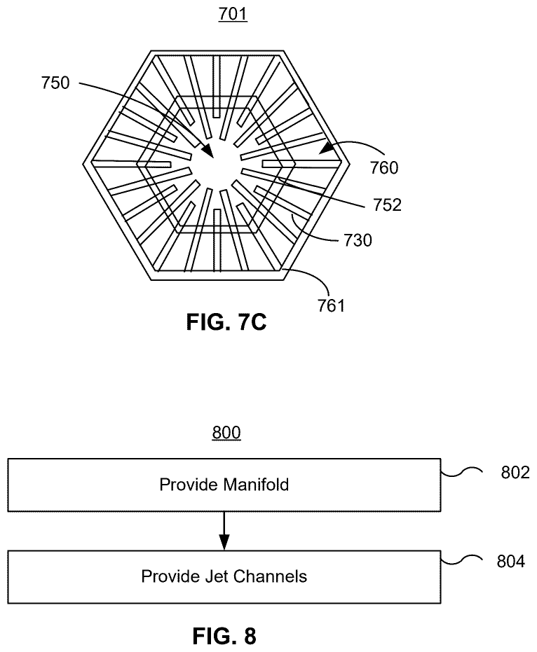

FIGS. 7A-7C depict various views of an embodiment of liquid cooling system 700. FIGS. 7A-7C may not be to scale. FIG. 7A depicts a cross-sectional view of cooling system 700 and cooling cell 701. FIG. 7B depicts a perspective view of cooling cell 701 indicating the flow of fluid and heat. FIG. 7C depicts a plan view of the cooling cell 701. For clarity, only portions of cooling system 700 are shown.

Cooling system 700 is used in conjunction with a heat-generating structure (not shown). The heat-generating structure may include semiconductor component(s) including individual integrated circuit components such as processors, other integrated circuit(s) and/or chip package(s); sensor(s); optical device(s); one or more batteries; other component(s) of an electronic device such as a computing device; heat spreaders; heat pipes; other electronic component(s) and/or other device(s) desired to be cooled. The heat-generating structure 102 may be a high-power dissipation component, such as a GPU. Consequently, heat-generating structure 102 may be referred to herein as a GPU.

Cooling system 700 includes inlet 712 and outlet 714 analogous to inlet 112 and outlet 114. Cooling system 700 also includes cooling cells 701. Each cooling cell 701 includes manifold 740 and jet channel subassembly 720 including base plate 722 and jet channel plate(s) 724 having jet channels 730. Cooling system 700 is analogous to cooling system 100. For example, jet channels 730, manifold 740, inlets 712, and outlet 714 are analogous to jet channels 130, manifold 140, inlets 112, and outlet 114, respectively. Thus, the structure and function of jet channels 730, manifold 740, inlets 712, and outlet 714 are analogous to those of jet channels 130, manifold 140, inlets 112, and outlet 114, respectively. Cooling system also includes inlet plenum 744 and outlet plenum 766 analogous to inlet plenum 244 and outlet plenum 266. Also shown are inlet shafts 756 and outlet region 766.

Cooling system may be further divided into cooling cells 701. In the embodiment shown, cooling cells 701 are hexagonal in footprint. However, another shape may be used. Cooling cells 701 may be arranged in an array having the desired shape. Thus, cooling system 700 may be extended to larger or smaller sizes having varying shapes. In some embodiments, additional inlet(s) and/or outlet(s) may be used. Further, the heights and/or sizes (e.g. footprint size) of cooling cells 701 may be varied. Thus, increased or decreased liquid flow may be provided in some regions. Portions of cooling cells 701 may include or consist of the same material or different materials. For example, base plate 722 and jet channel plate 724 may be formed of copper (and/or other highly thermally conductive material(s)) while manifold 740 may be formed of a thermally insulating material or copper (or other thermally conductive material). In some embodiments, a material such as copper may be desirable for the combination of its thermal conductivity and manufacturability.

In operation, liquid enters cooling system 700 via inlet 712. Liquid passes to inlet plenum 744 and to inlet shafts 746 for each cell 701. Inlet shafts 746 are connected to the inlet manifold channels 750 of each cell 701. Fluid travels down inlet manifold channel 750 through jet channels 730, and to outlet channels 760. Jet channels 730 are shown as radial. Although connecting inlet manifold channel 750 with outlet manifold channel 760, jet channels 730 need not be in a straight line. For example, curves or other shapes may be used. Further, not all jet channels need extend fully between inlet manifold channel 750 and outlet manifold channel 760. Heat is transferred to liquid traveling in jet channels 730 and carried to outlet manifold channel 760. The heated liquid travels up outlet manifold channel to outlet space 766 and to outlet plenum 764. Heated fluid may then exit via outlet 714.

Cooling system 700 may have improved performance and flexibility. Jet channels 730 are configured such that a boundary layer in a liquid at a surface of a jet channel is not substantially developed within at least the portion of the jet channel proximate to base plate 722. For example, the boundary layer may have apertures therein, be thinned, and/or not be present in the portion of the jet channel proximate to base plate 722. For example, jet channels 730 may have a length (between the center and outer edge of cell 701) of not more than (e.g., less than) five hundred micrometers. Thus, cooling system may more efficiently transfer heat from the device desired to be cooled. Use of cooling cells 701 allow for compensation of heating of the liquid used in system 700. For example, larger numbers of inlets 712 and outlets 714 may be used and evenly distributed across cooling system 700. Thus, issues due to heated fluid traveling through cooling system 700 may be mitigated. Further, the design of cells (e.g. the use of hexagonal cells through which fluid travels vertically and radially) may allow for local thermal/fluidic controls for specific groups of unit cells 701. Stated differently, groups of cells 701 may be configured differently. Some cells 701 may be taller, have wider inlet manifold channels 750, or otherwise be tailored for specific flow characteristics. Vertically integrated two dimensional manifolds 740 and structures 744, 764, 746, and 766 and may provide more uniform flow. Variation in the diameter of the central inlet manifold channel 750 may be used to control flow. Dimensions of jet channels 730 and/or other structures may be analogous to those in other embodiments. Variation in inlet manifold channels 750, outer chambers 766, and/or other dimensions may be used to compensate for heating of fluid and/or variations in temperature across the heat-generating structure. The height of inlet plenum 744 and outlet plenum 764 may be changed. Multiple inlet plenums 744 and/or outlet plenums 764 (e.g. an additional inlet plenum stacked on the inlet plenum shown) may be used to control the flow of liquid. In some embodiments, cells 701 may be approximately 0.5 mm or 1 mm-2.5 millimeters across/pitch in some embodiments (e.g. nominally 2 mm in some embodiments). In some embodiments, active elements may be used to drive liquid flow through cells 701 in a manner analogous to that discussed with respect to cooling system 200. For example, active elements might be used to drive flow into each inlet manifold channel 750. Thus, gravity and/or active elements/driving liquid may be used to provide liquid flow. Flow may be reversed in some embodiments. For example, liquid may flow from outlet manifold channel 760 through jet channels 730 to inlet manifold channel 750. Further, cells 701 may be arranged in arbitrary patterns (e.g. other than a rectangular array). Thus, the footprint of cells 701 and cooling system 700 may match the device desired to be cooled. Flexibility of system 700 may thus be further improved.

FIG. 8 is a flow-chart depicting an embodiment of method 800 for providing a liquid cooling system. Method 800 may include steps that are not depicted for simplicity. Method 800 is described in the context of liquid cooling systems 100, 100′, 100″, 200, and 700. However, method 800 may be used with other cooling systems including but not limited to other systems (e.g. cooling systems 300A, 300B, 3000C, 400A, 400B, 400C, 400D, 500A, 500B, 500C, 500D and/or 500E) described herein.

A manifold is provided, at 802. The manifold configured to be coupled to inlet(s) and one outlet(s). The manifold may be formed by micromachining or otherwise fabricating structures such as inlet and outlet manifold channels.

Jet channels are provided, at 804. The jet channels are microchannels that may be formed by micromachining or otherwise fabricating structures. The jet channels are configured such that a boundary layer in a liquid at a surface of a jet channel would not substantially be developed within at least the portion of the jet channel proximate to the heat-generating structure. Further, the jet channels are coupled with the manifold as part of 804. At least one of the jet channels or the manifold is configured to compensate for heating of the liquid in the cooling system. This may be accomplished by fabricating the manifold and/or jet channels as part of 802 and/or 804.

For example, at 802 manifold 240 or manifold 740 may be provided. At 804 jet channels 230 or 730 may be provided. Jet channel subassembly 220 or 720 may thus be provided. Manifold 240 or 740 may be attached to jet channel subassembly 220 or 720 as part of 804 or in a separate step. Fabrication of cooling system 200 and/or 700 may be completed. Thus, the cooling systems having the benefits described herein may be achieved.

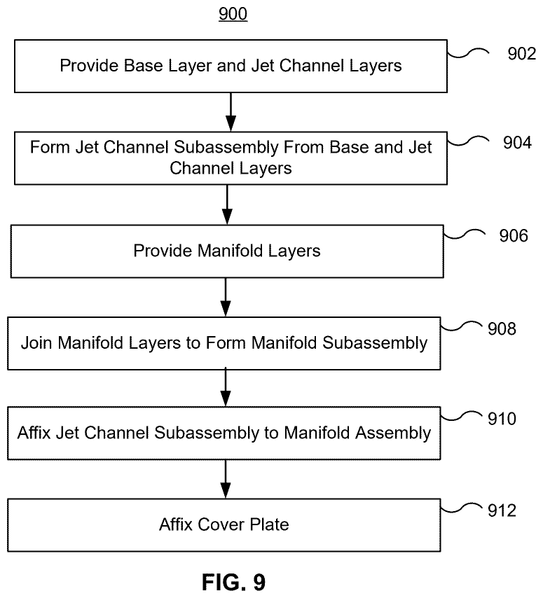

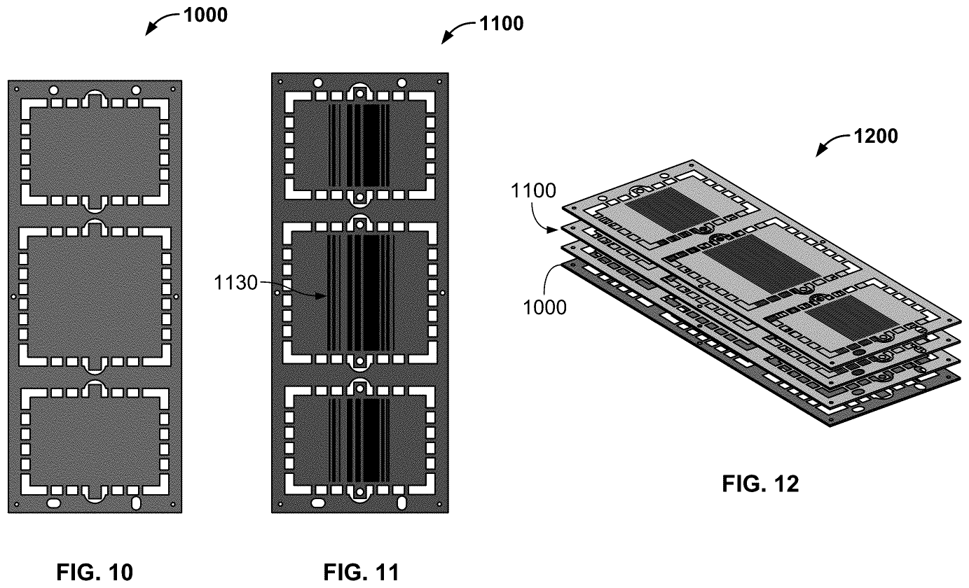

FIG. 9 is a flow-chart depicting an embodiment of method 900 for providing a liquid cooling system. Method 900 may include steps that are not depicted for simplicity. FIGS. 10-18B depict an embodiment of a liquid cooling system during fabrication. Thus, method 900 is described in the context of FIGS. 10-18B. However, method 900 may be used with other cooling systems including but not limited to other systems (e.g. cooling systems 300A, 300B, 3000C, 400A, 400B, 400C, 400D, 500A, 500B, 500C, 500D and/or 500E) described herein.

A base layer and jet channel layer(s) are provided, at 902. In some embodiments, 902 includes forming apertures, trenches and/or any other desired structures for the jet channels. In some embodiments, 902 includes forming apertures corresponding to the jet channels in each jet channel layer. Similarly, apertures, trenches, and/or other structures may be formed in the base layer. The number of base layers and jet channel layers prepared at 902 depends upon the desired thickness (height) and footprint of the jet channels. Etching through (or otherwise removing portions of) a thick layer may not be capable of fabricating jet channels having the desired aspect ratio. For example, a jet channel that is five hundred micrometers tall and one hundred micrometers wide may not be readily manufactured from a single layer. Thus, multiple layers may be used. For example, one base layer may be combined with three or more jet channel layers. In some embodiments, each layer is formed from a copper sheet. FIG. 10 depicts base layer 1000, while FIG. 11 depicts a jet channel layer 1100. Jet channel layer 1100 includes apertures 1130 corresponding to the jet channels. Apertures 1130 may be configured such that the jet channels being formed may compensate for heating of the fluid in the cooling system, pressure drops, and/or the desired flow characteristics.

At 904, the base layer and jet channel layers are affixed together. In some embodiments, this is accomplished using diffusion bonding process(es). The number of layers affixed together depends upon the desired height of the jet channel. Thus, a jet channel subassembly is formed. FIG. 12 depicts an exploded view of jet channel subassembly 1200. Thus, three jet channel layers 1100 are combined with base layer 1000 to form jet channel subassembly 1200.

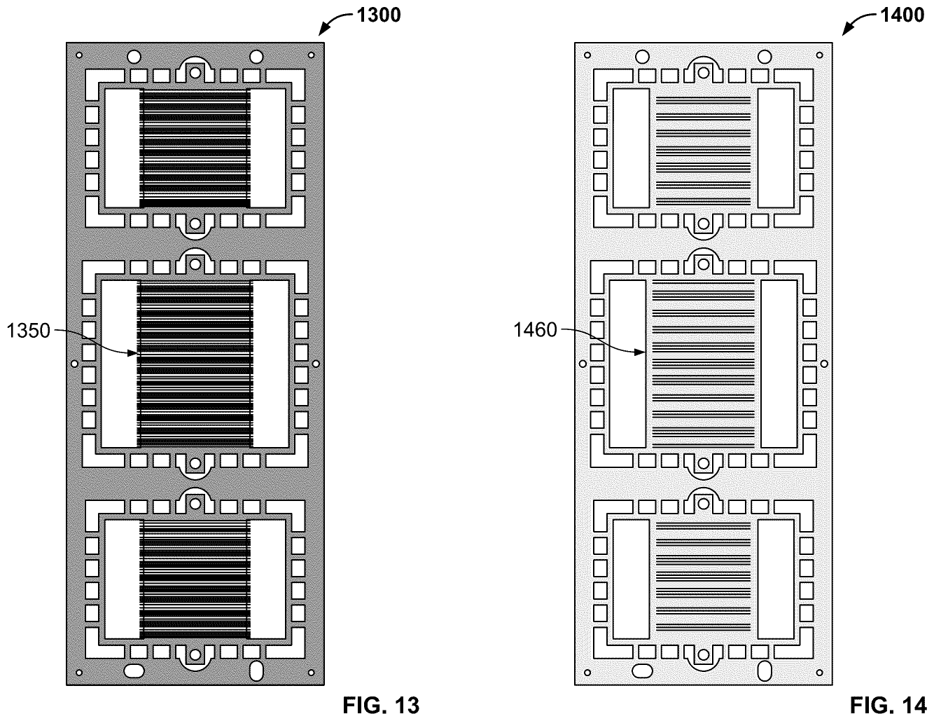

Layers for the manifold are provided, at 906. The number of manifold layers prepared at 902 depends upon the desired thickness (height) of the manifold and the sizes of the desired features. Multiple layers may be formed for analogous reasons as for the jet channels. In some embodiments, 902 includes providing layer(s) for the inlet manifold (inlet manifold layer(s)) and layer(s) for the outlet manifold (outlet manifold layer(s)). Thus, apertures, trenches, and/or other structures are formed in the inlet and outlet manifold layers for the desired components. In some embodiments, each layer is formed from a copper sheet. As part of 902, the apertures provided may be configured such that the manifold inlet and/or outlet channels being formed may compensate for heating of the fluid in the cooling system, pressure drops, and/or the desired flow characteristics. FIG. 13 depicts inlet manifold layer 1300. Inlet manifold layer 1300 includes apertures 1350 corresponding to the inlet manifold channels. Similarly, FIG. 14 depicts outlet manifold layer 1400. Inlet manifold layer 1400 includes apertures 1460 corresponding to the outlet manifold channels.

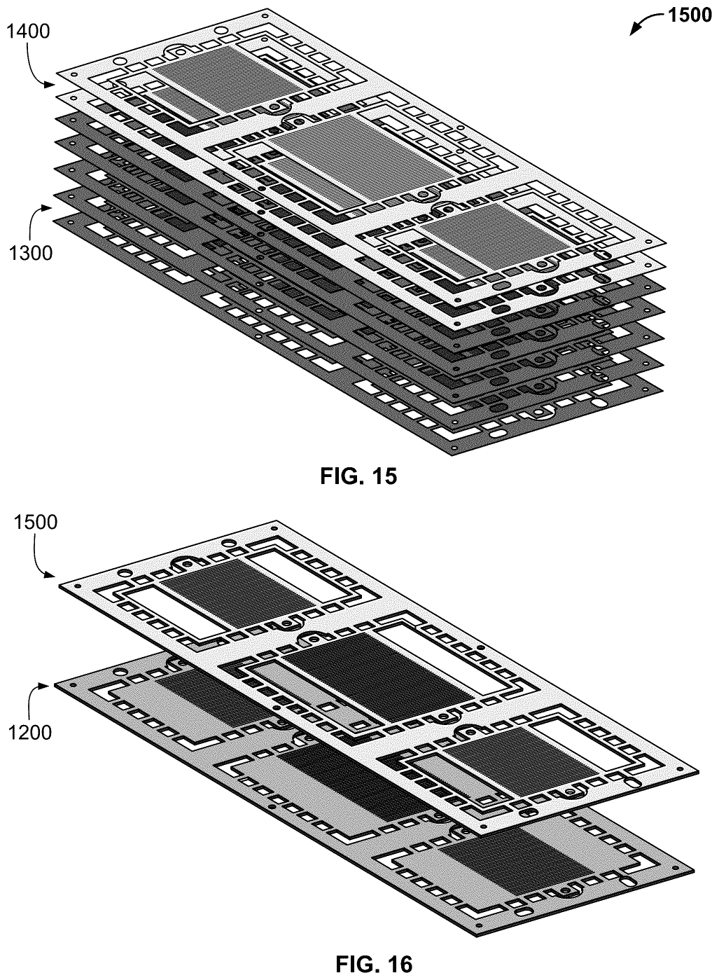

The manifold layers are joined to form a manifold subassembly, at 908. In some embodiments, this is accomplished using diffusion bonding process(es). The number of layers affixed together depends upon the desired height of the manifold channel. Thus, a manifold subassembly is formed. FIG. 15 depicts an exploded view of manifold subassembly 1500. Thus, five inlet manifold layers 1300 are combined with two outlet manifold layers 1400 to form manifold subassembly 1500.

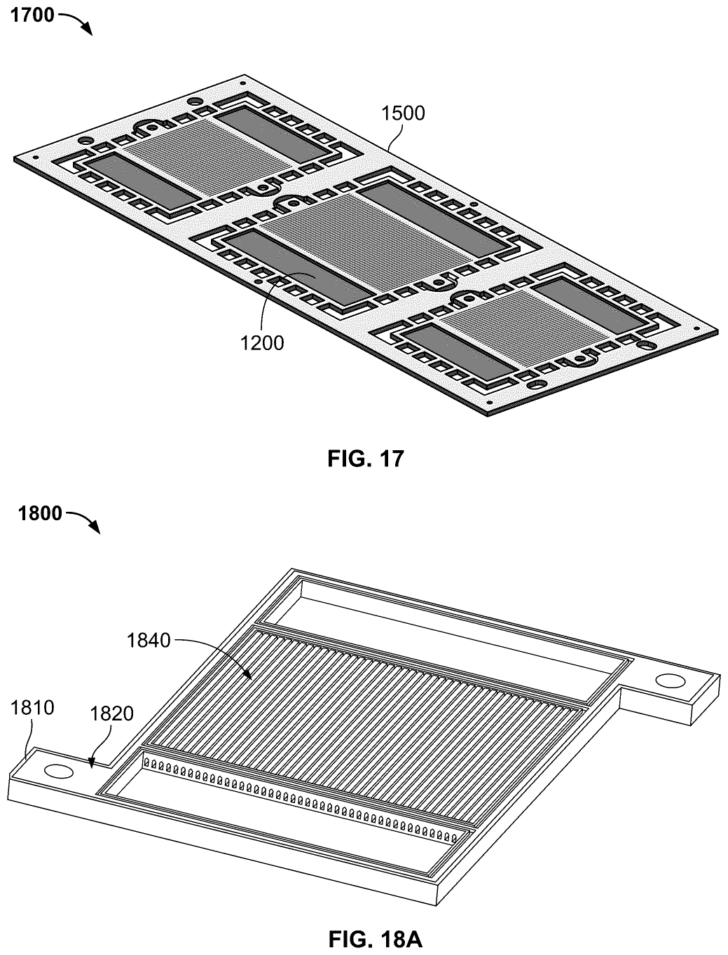

Manifold subassembly 1500 and jet channel subassembly 1200 are affixed together, at 910. In some embodiments, 910 is performed using a diffusion bonding process. FIG. 16 depicts assembly manifold subassembly 1500 together with jet channel subassembly 1200. FIG. 17 depicts subassembly 1700 formed after manifold subassembly 1500 and jet channel subassembly 1300 have been affixed together. Fabrication of the cooling system continues. Fabrication of the cooling system continues.

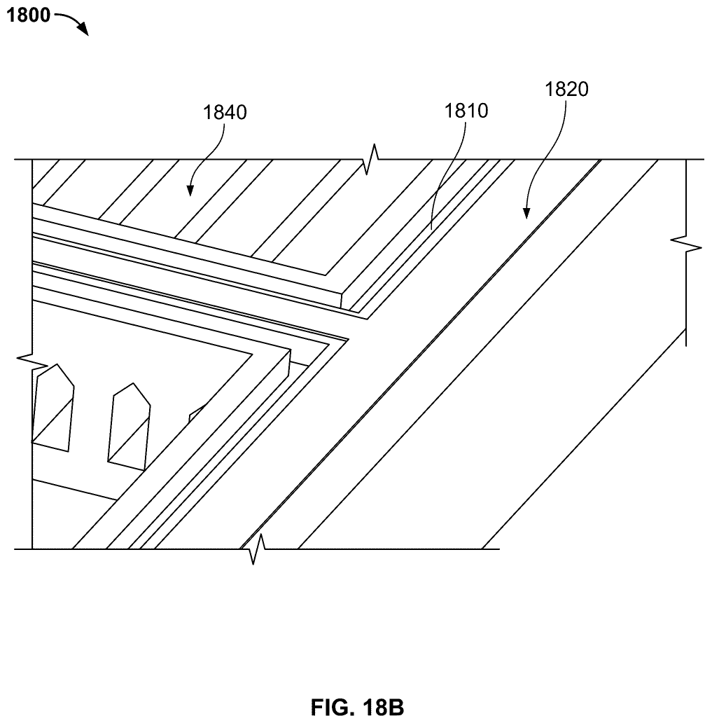

A cover plate is affixed to the top of the subassembly 1700, at 912. Thus, inlet and outlet plenums are formed above the manifold. In some embodiments, a brazing process is used. FIGS. 18A and 18B depict the subassembly 1800 before the cover plate is attached. Manifold 1840 may still be seen. The jet channels of jet channel subassembly 1200 may be below manifold 1840. Brazing alloy 1820 has been placed in brazing dam 1810. Brazing alloy may include copper phosphorus, copper zinc, and/or other materials. Brazing dam 1810 allows for heating and reflow of brazing metal 1820 without leakage onto other portions of subassembly 1800. Such leakage may adversely affect performance. The cooling system provided may be analogous to cooling system 200.

Thus, using method 900, a liquid cooling system cooling system analogous to cooling systems 100, 100′, 100″, 200, 300A, 300B, 300C, 400A, 400B, 400C, 500A, 500B, 500C, and 700 may be fabricated. Consequently, the benefits described herein may be achieved.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A liquid cooling system, comprising:
at least one inlet;
at least one outlet;
a manifold coupled to the at least one inlet and the at least one outlet; and
a plurality of jet channels coupled to the manifold, the plurality of jet channels being microchannels, a portion of each of the plurality of jet channels being proximate to a heat-generating structure, the plurality of jet channels being configured such that a boundary layer in a liquid at a surface of a jet channel of the plurality of jet channels is not substantially developed within at least the portion of the jet channel proximate to the heat-generating structure, the plurality of jet channels being configured to receive fluid from the at least one inlet through the manifold and to provide the fluid through the manifold to the at least one outlet;
wherein at least one of the plurality of jet channels or the manifold is configured to compensate for heating of the liquid in the liquid cooling system.

2. The liquid cooling system of claim 1, wherein the heat-generating structure includes at least one of a heat spreader, a vapor chamber, a semiconductor device, an integrated circuit, an optical device, a battery, a sensor, or a heat pipe.

3. The liquid cooling system of claim of 1, wherein the jet channel has a width of at least fifty micrometers and not more than five hundred micrometers and a length of at least fifty micrometers and not more than five hundred micrometers.

4. The liquid cooling system of claim 1, wherein the manifold further includes:
an inlet manifold having an inlet plenum and a plurality of manifold channels between the inlet plenum and the plurality of jet channels; and
an outlet manifold having an outlet plenum and a plurality of outlet manifold channels, the plurality of jet channels being between the inlet plenum and the outlet plenum.

5. The liquid cooling system of claim 4, a first portion of the plurality of jet channels near the at least one inlet being at least one of shorter than a second portion of the plurality of jet channels distal from the at least one inlet, at a different pitch from than the second portion of the plurality of jet channels distal from the at least one inlet, or narrower than the second portion of the plurality of jet channels distal from the at least one inlet.

6. The liquid cooling system of claim 4, wherein a first portion of the inlet manifold proximate to the inlet is at least one of narrower or shorter than a second portion of the inlet manifold distal from the inlet.

7. The liquid cooling system of claim 1, wherein a first portion of the plurality of jet channels is coupled with the at least one inlet, a second portion of the plurality of jet channels is coupled with the at least one outlet, the portion of the plurality of jet channels proximate to the heat-generating structure is between the first and second portions of the jet channels and has a length not exceeding five hundred micrometers.

8. The liquid cooling system of claim 1, wherein each of the plurality of jet channels has a first portion coupled to the manifold, a second portion at a first nonzero angle from the first portion, and a third portion coupled to the manifold and oriented at a second nonzero angle from the second portion, the third portion being coupled with the at least one outlet.

9. The liquid cooling system of claim 1, wherein the manifold includes a central shaft coupled to the inlet and through which the liquid passes.

10. The liquid cooling system of claim 9, wherein each of the plurality of jet channels is configured to carry the liquid from the central shaft to an outer manifold or from the outer manifold to the central shaft, the manifold including the outer manifold.

11. The liquid cooling system of claim 10, wherein the plurality of jet channels is oriented radially from the central shaft to the outer manifold.

12. The liquid cooling system of claim 9, wherein the liquid cooling system has a hexagonal footprint.

13. The liquid cooling system of claim 12, wherein the cooling system is one of a plurality of cooling systems having the hexagonal footprint and configured with sides that are adjacent.

14. The liquid cooling system of claim 13, wherein at least one of a width or height of the central shaft may be varied between individual cooling systems for at least one of to compensate for heating of the liquid as the liquid travels through the cooling system or based on hot spots in the heat-generating structure.

15. The liquid cooling system of claims 1, further comprising:
at least one active component configured to drive a liquid flow through the manifold and the plurality of jet channels.

16. A liquid cooling system, comprising:
at least one inlet;
at least one outlet;
a manifold including an inlet manifold and an outlet manifold, the inlet manifold coupled to the at least one inlet, and the outlet manifold coupled to the at least one outlet; and
a plurality of jet channels coupled with the manifold, the plurality of jet channels being microchannels, a portion of each of the plurality of jet channels being proximate to a heat-generating structure, the plurality of jet channels being configured to receive a liquid from the inlet manifold and to provide the liquid to the outlet manifold, the portion of each of the plurality of jet channels proximate to the heat-generating structure having a length not exceeding five hundred micrometers;
wherein at least one of the plurality of jet channels or the manifold is configured to compensate for heating of the liquid in the liquid cooling system.

17. A method for providing a liquid cooling system, comprising:
providing a manifold configured to be coupled to at least one inlet and at least one outlet; and
providing a plurality of jet channels, the plurality of jet channels being microchannels, a portion of each of the plurality of jet channels being proximate to a heat-generating structure, the plurality of jet channels being configured such that a boundary layer in a liquid at a surface of a jet channel of the plurality of jet channels is not substantially developed within at least the portion of the jet channel proximate to the heat-generating structure;
wherein at least one of the plurality of jet channels or the manifold is configured to compensate for heating of the liquid in the liquid cooling system.

18. The method of claim 17, wherein the providing the plurality of jet channels further includes:
providing a jet channel subassembly including:
providing a base layer;
providing a plurality of jet channel layers, each of the plurality of jet channel layers having a plurality of apertures corresponding to the plurality of jet channels; and
diffusion bonding the plurality of jet channel layers together with the base layer. in

19. The method of claim 18, wherein the manifold includes a plurality of manifold channels configured to be fluidically coupled with the plurality of jet channels, the providing the manifold further includes:
providing a plurality of manifold layers including a plurality of manifold apertures corresponding to the plurality of manifold channels; and
diffusion bonding the plurality of manifold layers together.

20. The method of claim 19, further comprising:
diffusion bonding the manifold with the jet channel subassembly; and
affixing a cover plate to the manifold, the cover plate including at least one of the at least one inlet or the at least one outlet, the affixing further including a brazing process.
